(19) United States
(12) Patent Application Publication
(10) Pub. No.: US 2017/0077331 A1
(43) Pub. Date: Mar. 16, 2017

(54) SEALING FILM FOR SOLAR CELL AND METHOD OF MANUFACTURING THE SAME, SEALING STRUCTURE FOR SOLAR CELL MODULE

(71) Applicants: Industrial Technology Research Institute, Hsinchu (TW); Microcosm Technology Co., Ltd., Tainan City (TW)

(72) Inventors: Chien-Rong Huang, Hsinchu City (TW); Tung-Po Hsieh, Taipei City (TW); Tang-Chieh Huang, Chiayi County (TW)

(21) Appl. No.: 14/977,666

(22) Filed: Dec. 22, 2015

(30) Foreign Application Priority Data
Sep. 11, 2015 (TW) 104130076

(51) Int. Cl. H01L 31/048; H01L 31/05

(52) U.S. Cl. CPC H01L 31/048; H01L 31/0504

(57) ABSTRACT

A sealing film for a solar cell and a method of manufacturing the same, and a sealing structure for a solar cell module having the sealing film for a solar cell are provided. The sealing film for a solar cell includes a substrate and an adhesive layer having a conducting wire structure, wherein the adhesive layer having the conducting wire structure is located on the substrate, and the conducting wire structure is in contact with the substrate. Via the sealing film for a solar cell having the above configuration, a plurality of solar cell units not electrically connected to one another can be electrically connected by using the conducting wire structure of the sealing film for a solar cell while sealing and laminating the solar cell.

### CROSS REFERENCE TO RELATED APPLICATIONS

The present application is based on, and claims priority from, Taiwan Application Serial Number 104130076, filed on Sep. 11, 2015, the disclosure of which is hereby incorporated by reference herein in its entirety.

### TECHNICAL FIELD

The disclosure relates to a sealing technique for a solar cell module and a method of manufacturing the same, and more particularly, to a sealing film for a solar cell and a method of manufacturing the same, and a sealing structure of a solar cell module.

### BACKGROUND

Solar energy is an inexhaustible energy free of pollution. Therefore, when faced with issues such as pollution and shortage derived from fossil fuels, how to utilize the solar energy effectively is the primary concern. In particular, the solar cell can be used to directly convert solar energy into electrical energy and therefore has become the focus of current development.

To reduce sealing costs of the solar cell module and increase the versatility thereof, in addition to an encapsulant, the front sheet and the back sheet have extensively adopted a flexible polymer substrate. To further reduce the process steps of sealing the solar cell module to reduce the processing costs of sealing, many different sealing laminated structures having a conducting wire structure are proposed in the hopes of completing the functions of interconnection and sealing of the solar cell module in one lamination process. Moreover, a technique in which interconnection of cells can be completed via a single-side treatment method on the structural design of a module is desired, such that the sealing process is more simplified and the effect of automatic integration of module sealing can be readily achieved. In a traditional solar cell module, the first electrode and the second electrode of the solar cell units are located on the front and back of the cell, and the conducting wire or conducting layer between the front and back is needed to achieve the effect of electrical connection of a plurality of solar cell units.

In another traditional solar cell module, an adhesive layer is used to combine the conducting wire or conducting layer and the substrate to electrically connect a plurality of solar cell units, but a thermoplastic or non-cross-linked thermoset adhesive layer is softened during heating, and may even melt, thus causing the conducting wire or conducting layer to slide and causing difficulty in the control of the position of electrical bonding. Moreover, localized surface heating or other plasma reactions generated during the conducting layer deposition process or during the dry etching process of the conducting layer also make the surface of adhesive layer generate a cross-linking effect, such that sealing performance is lost.

Moreover, another traditional solar cell module includes a substrate and a flexible conducting wire sheet formed by another substrate and a conducting layer, an adhesive layer disposed between the substrate and the flexible conducting wire sheet, and a plurality of solar cell units electrically connected via the conducting layer on the flexible conducting wire sheet. In such a sealing laminated structure, although the flexible conducting wire sheet can achieve the function of interconnection of the solar cell units, since the flexible conducting wire sheet does not have the bonding function of module sealing, an extra adhesive layer is needed to achieve the function of sealing with the substrate. Moreover, substantive bonding may not occur between the flexible conducting wire sheet and solar unit cells, thus readily causing the issue of film layer separation due to, for instance, factors such as moisture and temperature. Moreover, the metal layer of a flexible conducting wire is usually manufactured via sputtering followed by etching, and therefore the thickness of the metal layer is limited and the resistance is greater, such that the demand of operating the solar cell in a large current cannot be satisfied. However, to maintain the function of the adhesive layer and the module strength, the area of the single flexible conducting wire sheet cannot be too great, sufficient bonding space of the adhesive layer and the solar unit cells needs to be kept between each of the flexible conducting wire sheets, and therefore the manufacture of the flexible conducting wire sheet does not have the effect of one-time thermal lamination.

Moreover, in a traditional solar cell module, since a film layer such as an adhesive layer is generally present between the patterned conducting layer and the substrate, a lead wire cannot be readily pulled out by punching a hole at the substrate side of the sealing laminated structure in certain special applications.

In view of the above technical issues, industries are currently urgently seeking a solution to completing interconnection and sealing of the solar cell module in one lamination process.

Therefore, currently, industries mostly focus on the development of a module structure and a manufacturing technique: such as how to reduce the series resistance of solar cell units, reduce front and back side interactive conducting ribbon stress effect, an interconnection technique of, for instance, preventing displacement to the solder position of a conducting ribbon, and a sealing technique of a sealing module for a solar cell. However, a sealing structure for a solar cell capable of effectively providing electrical interconnection efficacy, module strength, and convenience of single-side manufacture is still lacking.

### SUMMARY

The disclosure provides a sealing film for a solar cell includes a substrate and an adhesive layer having a conducting wire structure. The adhesive layer having the conducting wire structure is disposed on the substrate, and the conducting wire structure is in contact with the substrate.

The sealing structure for a solar cell module of the disclosure includes the sealing film for a solar cell and the solar cell. The sealing film for a solar cell includes a substrate and an adhesive layer having a conducting wire structure, wherein the adhesive layer having the conducting wire structure is disposed on the substrate, and the conducting wire structure is in contact with the substrate. The solar cell includes a plurality of solar cell units, wherein the adhesive layer is between the substrate and the solar cell units, and the conducting wire structure is in contact with the plurality of solar cell units and the substrate.

The method of manufacturing a sealing film for a solar cell of the disclosure includes the following steps. A substrate is provided; and an adhesive layer having a conducting wire structure is formed on the substrate, wherein the conducting wire structure is in contact with the substrate.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a structural schematic of a sealing film for a solar cell according to the first embodiment of the disclosure, and FIG. 1B is a cross-sectional schematic of a sealing film for a solar cell along line BB′ of FIG. 1A.

FIG. 2 is a schematic of the manufacturing method of the first embodiment of the method of manufacturing a sealing film for a solar cell of the disclosure.

FIG. 3 is a schematic of the manufacturing method of the second embodiment of the method of manufacturing a sealing film for a solar cell of the disclosure.

FIG. 4A to FIG. 4D are flow charts of the manufacturing method of the third embodiment of the method of manufacturing a sealing film for a solar cell of the disclosure.

FIG. 5A and FIG. 5B are schematics of the first embodiment of the sealing structure for a solar cell module of the disclosure.

FIG. 6A and FIG. 6B show schematics of the second embodiment of the sealing structure for a solar cell module of the disclosure.

FIG. 7A and FIG. 7B show schematics of the third embodiment of the sealing structure for a solar cell module of the disclosure.

FIG. 8A and FIG. 8B are flow charts of the method of manufacturing a sealing structure for a solar cell module of the disclosure.

FIG. 9 is a flow chart of an embodiment of the method of manufacturing a sealing structure for a solar cell module of the third embodiment of the method of manufacturing a sealing film for a solar cell of the disclosure.

### DETAILED DESCRIPTION OF DISCLOSED EMBODIMENTS

The disclosure is described in the specification with reference to accompanying figures. Embodiments are shown in the figures, but the disclosure can still have many forms of implementation, and the disclosure should not be construed as limited to the embodiments provided in the specification. In the figures, for clarity, the size and the relative size of each layer and each region may be exaggerated.

In the following, when a device or layer is referred to as “located on another device or layer” or “located at the left side or the right side of another device”, the device or layer can be directly located on another device or layer or an intermediate device or layer can be included. Moreover, when a device is “in contact with another device or layer”, an intermediate device or layer is not included between the two. Spatially relative terms used in the specification such as “under (or on, to the left of, to the right of . . . )” and similar terms thereof describe the relationship of a device or layer in the figures to another device or layer. Such spatially relative terms should include devices in use or operation, and include different directions in addition to the directions shown in the figures. For instance, if a device in a figure is turned over, then the device described to be located “on” other devices or layers is located “under” the other devices or layers.

Sealing Film for Solar Cell

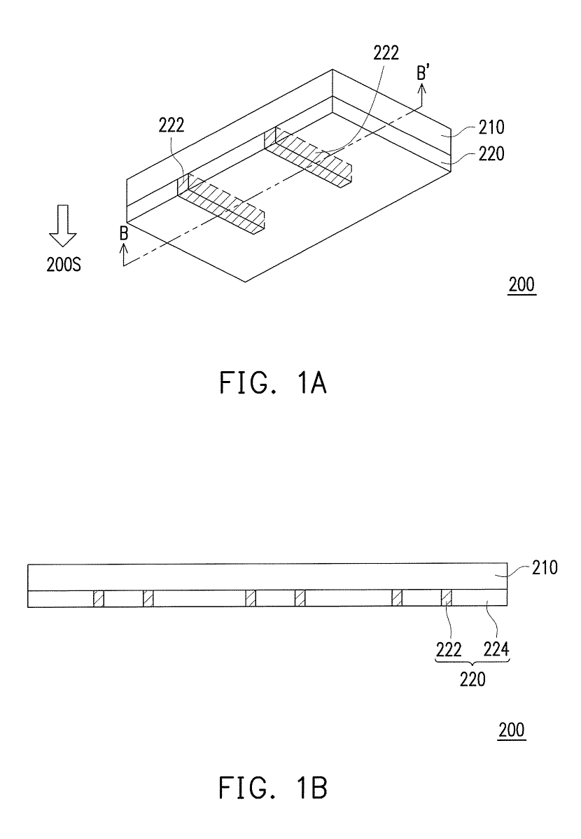

FIG. 1A is a structural schematic of a sealing film for a solar cell according to the first embodiment of the disclosure, and FIG. 1B is a cross-sectional schematic of a sealing film for a solar cell along line BB′ of FIG. 1A. Referring to FIG. 1A and FIG. 1B, a sealing film 200 for a solar cell includes a substrate 210 and an adhesive layer 220 having a conducting wire structure 222, and the adhesive layer 220 having the conducting wire structure 222 is disposed on the substrate 210. The substrate 210 can be sealing substrate, for instance, a glass or a flexible polymer film, fluoropolymer, such as polyethylene terephthalate (PET), polyethylene naphthalate (PEN), polycarbonate (PC), poly(ethylene-co-tetrafluoroethylene) (ETFE), polyetheretherketone (PEEK), poly(tetrafluoroethylene-co-hexafluoropropylene) (FEP), polyvinylfluoride (PVF), polyvinylidene fluoride (PVDF), perfluoroalkoxy (PFA), polychlorotrifluoroethane (PCTFE), or polyimide (PI). The material of the adhesive layer 220 is, for instance, a cross-linkable thermoset or thermoplastic material such as ethylene vinyl acetate (EVA), polyvinyl butyral (PVB), thermoplastic polyurethane (TPU), silicone, silicone gel, polydimethyl siloxane (PDMS), thermal polymer olefin (TPO), acrylate, ionomer, acid-modified polyolefin, anhydride-modified polyolefin, polyamide, or anhydride-modified polypropylene. Of course, the substrate 210 and the adhesive layer 220 can also be other materials, and the disclosure is not limited thereto. The material of the adhesive layer 220 can be formed by dissolving into a liquid state by using a suitable organic solvent. For instance, ethylene vinyl acetate (EVA) can be formed into a liquid state via an organic solvent such as xylene, p-xylene, toluene, tetrahydrofuran (THF), or butanone, and then an adhesive layer can be formed via a method of coating and drying. Moreover, the substrate 210 can also adopt a single-layer structure having the above material as a protective film according to product demand, and can also adopt a laminated layer structure of materials having moisture barrier, UV absorption, weather-ability, and scratch-resistance as the protective film and the supporting layer as needed, and the material and the structure of the substrate 210 are not limited thereto.

The sealing film 200 for a solar cell is electrically connected to the solar cell via the adhesive layer 220 in a subsequent process (referred to as an electrode connecting side 200S). It should be mentioned that, in the sealing film 200 for a solar cell of the disclosure, the conducting wire structure 222 is an architecture in direct contact with the substrate 210. Via the full or partial contact of the conducting wire structure 222 and the substrate 210 in the adhesive layer 220, the contact force is formed between the conducting wire structure 222 and the substrate 210, so that in a subsequent process such as heating and melting of the adhesive layer 220 material, lateral displacement due to a process such as lamination does not occur to the adhesive layer 220 between the conducting wire structure 222 and the solar cell. As a result, accurate position of electrical connection can be ensured.

More specifically, the conducting wire structure 222 passes through the thickness direction of the adhesive layer 220, that is, the conducting wire structure 222 is embedded in the adhesive layer 220. Moreover, in the present embodiment, the surfaces of the conducting wire structure 222 and the adhesive layer 220 are level, but in other embodiments, the conducting wire structure 222 can also be protruded beyond the surface of the adhesive layer 220, and the disclosure is not limited thereto.

The sealing film 200 for a solar cell of the disclosure integrates the conducting wire structure 222 used to interconnect the solar cell units, the sealing protective substrate 210 for sealing the solar cell, and the patterned adhesive material adhering the solar cell and the substrate 210 when the solar cell is sealed. Accordingly, when a subsequent process is performed on the solar cell via the sealing film 200 for a solar cell of the disclosure, interconnection and sealing of the solar cell module can be completed via only one subsequent thermal lamination process.

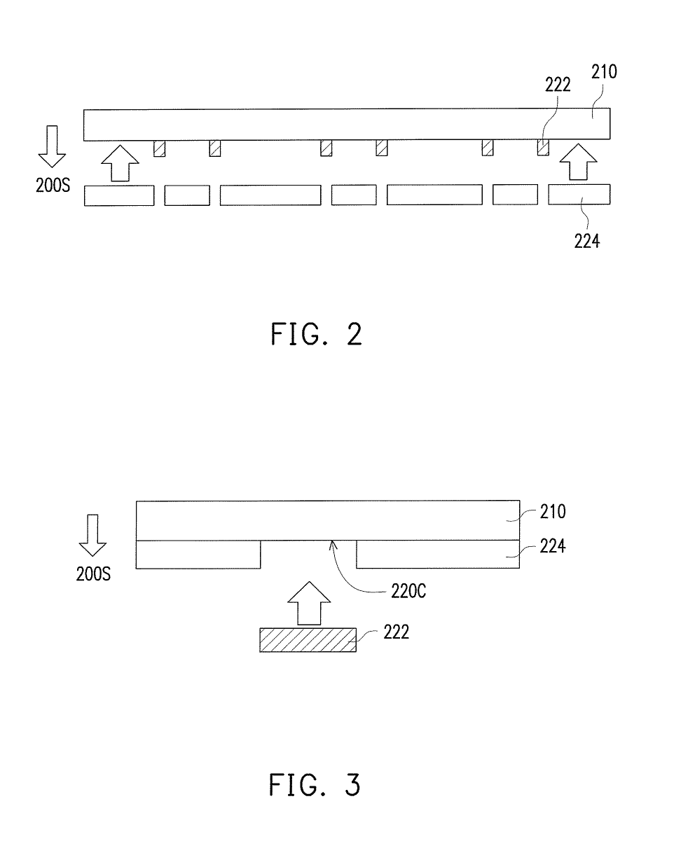

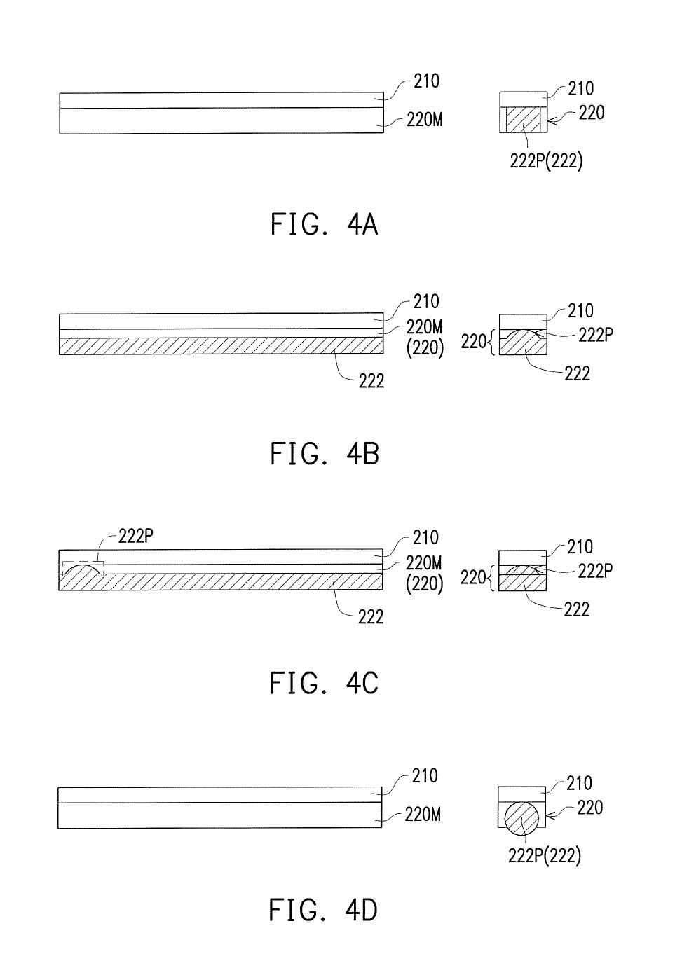

The method of manufacturing the sealing film 200 for a solar cell of the disclosure can include, for instance, a screen printing electrode contact method shown in FIG. 2, a conducting ribbon channel method shown in FIG. 3, or a conducting ribbon pressing method shown in FIG. 4A to FIG. 4D. However, the disclosure is not limited thereto.

Method of Manufacturing Sealing Film for Solar Cell

FIG. 2 is a schematic of the manufacturing method of the first embodiment of the method of manufacturing a sealing film for a solar cell of the disclosure. As shown in FIG. 2, in the present embodiment, a substrate 210 is provided, and the conducting wire structure 222 in contact with the substrate 210 is first formed on the substrate 210. The method of directly forming the conducting wire structure 222 on the electrode connecting side 200S of the substrate 210 includes, for instance, screen printing a conductive silver paste, a copper paste, or a silver-copper paste circuit on the substrate 210 of a polymer film, and coating or adhering one layer of low-temperature solder (such as an In/Sn alloy or a Sn/Bi alloy) on the cell side, and curing the conductive paste. Then, a patterned adhesive layer 224 is formed in a region outside the conducting wire structure 222 on the substrate 210, and the method of forming the patterned adhesive layer 224 in the region outside the conducting wire structure 222 on the substrate 210 can include using a thermoset ethylene vinyl acetate (EVA) film as the adhesive layer 220 material, then coating the photosensitive adhesive layer 220 via an lamination/transfer method, a method of cutting and peeling via the adhesive layer 220, or via a slurry, and then forming the patterned adhesive layer 224 via a method such as exposure and development. Accordingly, the adhesive layer 220 integrated from the patterned adhesive layer 224 and the conducting wire structure 222 can be obtained on the substrate 210.

FIG. 3 is a schematic of the manufacturing method of the second embodiment of the method of manufacturing a sealing film for a solar cell of the disclosure. As shown in FIG. 3, in the present embodiment, a substrate 210 is provided, and a patterned adhesive layer 224 is first formed on the substrate 210. The method of forming the patterned adhesive layer 224 on the substrate 210 includes, for instance, forming the patterned adhesive layer 224 having a channel 220C on the substrate 210 via a method such as attach/transfer by using an ethylene vinyl acetate (EVA) film as the adhesive layer 220 material, cutting and peeling via the adhesive layer 220, or coating a photosensitive adhesive layer with an adhesive layer 220 slurry and performing exposure and development, wherein the channel 220C corresponds to a predetermined forming region of the conducting wire structure 222, and the depth thereof can be, for instance, 50 μm to 450 μm. Then, the conducting wire structure 222 is formed in a region outside (i.e., in the above channel 220C) the patterned adhesive layer 224 on the substrate 210, so as to form the adhesive layer 220 formed by the patterned adhesive layer 224 and the conducting wire structure 222. The method of forming the conducting wire structure 222 in the channel 220C can include, for instance, a method of conductive paste injection, a method of screen printing and UV/thermal curing forming, or metal foil lamination and a lithography/etching/electroplating coppering process. The conducting wire structure 222 formed accordingly is directly and securely formed on the substrate 210 such that the structure of the conducting wire structure 222 is in direct contact with the substrate 210. The conducting wire structure 222 formed accordingly is also structurally in complete contact with the substrate 210.

FIG. 4A to FIG. 4D are flow charts of the manufacturing method of the third embodiment of the method of manufacturing a sealing film for a solar cell of the disclosure, wherein the left side and the right side of FIG. 4A to FIG. 4D are respectively a side view and a cross-section of the method of manufacturing a sealing film for a solar cell. As shown in the side view on the left side of FIG. 4A, a substrate 210 is provided, and an adhesive material layer 220M is formed on the substrate 210. Then, as shown in the cross-sections on the right of FIG. 4A to FIG. 4D, the conducting wire structure 222 is embedded in the adhesive material layer 220M, such that the conducting wire structure 222 is in contact with the substrate 210.

Specifically, one of the implementations of the side view on the left side of FIG. 4A to FIG. 4D includes, for instance: first coating the adhesive material layer 220M having a thickness of, for instance, 50 μm to 450 μm on the substrate 210 of, for instance, a polymer film. Then, a conductive metal ribbon or metal wire having a thickness greater than or equal to that of the adhesive material layer 220M is provided, and then coating/adhering/pre-soldering of a low-temperature solder (such as an In/Sn alloy or a Sn/Bi alloy) is performed at a predetermined connecting side of the conducting metal ribbon or the metal wire and the electrode, such that the conducting metal ribbon or the metal wire containing a low-temperature solder forms the conducting wire structure 222. Then, the adhesive material layer 220M is heated to soften the adhesive material layer 220M, but a molten state of cross-link deterioration does not occur, such as a thermoset EVA of 60° C. to 80° C. Then, the metal conducting ribbon or wire containing the low-temperature solder is pressurized and embedded in the adhesive layer 220, such that the conducting wire structure 222 containing the low-temperature solder and the substrate 210 are fully or partially in contact.

In another embodiment of the side view on the left side of FIG. 4A to FIG. 4D, the adhesive material layer 220M having a thickness of, for instance, 50 μm to 450 μm dissolved in an organic solvent can also be first coated on, for instance, the substrate 210 such as a polymer film. In the present embodiment, after the conducting wire structure 222 is embedded in the adhesive material layer 220M, heating and drying are performed on the adhesive material layer 220M under the conditions of, for instance, 10 minutes/50° C. to remove the organic solvent thereof, so as to form an adhesive layer integrating the conducting wire structure 222 into a single film.

In the sealing film for a solar cell manufactured by the manufacturing method of the third embodiment of FIG. 4A to FIG. 4D, the manner in which the conducting wire structure 222 and the substrate 210 are in contact can be in the form shown in the cross-sections on the right side of FIG. 4A to FIG. 4D. The conducting wire structure 222 includes a plurality of protrusions 222P in contact with the substrate 210, and the manner in which each of the protrusions 222P is in contact with the substrate 210 can be a planar island-shaped pattern in contact with the substrate 210 via a flat top surface thereof as shown on the right side of FIG. 4A. The conducting metal wire in the present embodiment is, for instance, a general planar solar cell (PV) conducting metal ribbon, such that the formed conducting metal ribbon and the substrate 210 are in a state of full contact with each other.

Of course, each of the protrusions 222P of the conducting wire structure 222 can also be in contact with the substrate 210 via a round top surface thereof as shown on the right side of FIG. 4B to FIG. 4D. The conducting metal wire in the present embodiment is, for instance, a round conducting wire for which the center has a protruding shape, a conducting metal ribbon for which the center has a protruding shape manufactured via stamping or other methods, or a conducting metal ribbon for which a portion of the center has a protruding shape, such that the conducting metal ribbon having a protruding center or the conducting metal ribbon having a partial protruding center pushes the adhesive material layer to two sides via a pushing effect of a curved surface of a round top surface. As a result, the formed conducting metal wire and the substrate 210 are in a state of full or partial contact with each other.

Via the integration of the new conducting wire, the adhesive layer, and the sealing film for a solar cell of the substrate of the present application, issues of, for instance, sealing, electrical interconnection, and simplified process in the prior art can be solved. Moreover, the sealing film for a solar cell of the disclosure readily adopts a roll-to-roll automated method to first integrate the conducting wire structure, the patterned adhesive layer, and the substrate into a single film. Accordingly, after the sealing film for a solar cell and the solar cell are aligned and laminated in a subsequent process of the solar cell module, interconnection and sealing of the module can be completed via a thermal lamination process.

Sealing Structure for Solar Cell Module

When the sealing film for a solar cell of the disclosure is used to perform sealing and electrical connection on the solar cell, the effects of sealing and electrical interconnection can be achieved at the same time in one thermal lamination process of the solar cell module. Moreover, in comparison to prior art, the sealing structure for a solar cell module of the disclosure does not require an additional adhesive layer to perform a paving membrane process, and since the sealing film for a solar cell of the disclosure is a single-side electrical interconnection structure, the process can therefore be effectively simplified.

Moreover, the conducting wire structure in the sealing film for a solar cell of the disclosure can already replace the function of the conducting ribbon for sealing and soldering in prior art, and as a result, the usage amount of silver paste for electrically interconnecting the conducting ribbon and the bus bar of a solar cell in prior art can be reduced, and the stress effect of the conducting ribbon can be reduced. Moreover, the use of the sealing film for a solar cell of the disclosure can prevent another metal film coating or electroplating thickening process performed on the adhesive layer in the sealing process of the solar cell module, and metal film coating and etching of the entire surface are not needed. As a result, the adhesive layer in the sealing film for a solar cell can be prevented from losing the function of adherence in a high-temperature process such as a subsequent metal film deposition, thus preventing the issue of film layer separation, and reducing the material of the conducting wire. To clearly describe the use of the sealing structure for a solar cell module and the method of manufacturing the same of the disclosure, the sealing structure for a solar cell module and the method of manufacturing the same are described below.

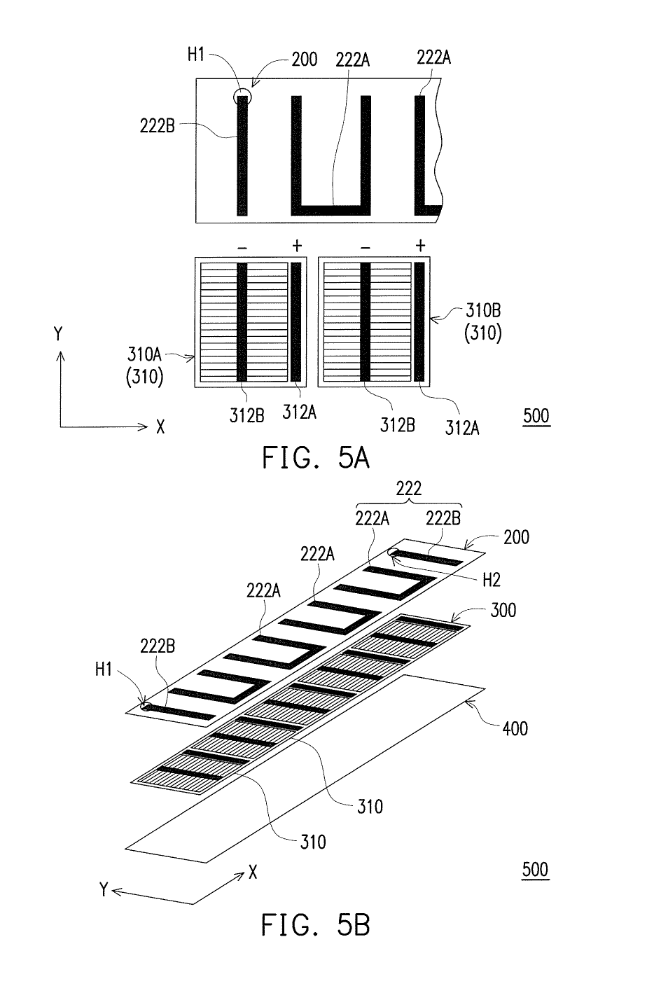

FIG. 5A and FIG. 5B are schematics according to the first embodiment of the sealing structure for a solar cell module of the disclosure, wherein FIG. 5A shows a top view of the sealing film for a solar cell and the substrate in the sealing structure for a solar cell module of the first embodiment, and FIG. 5B shows a schematic of a laminated structure of the sealing structure for a solar cell module of the first embodiment. It should be mentioned that, in a sealing structure 500 for a solar cell module of the present embodiment, the conducting wire structure 222 in the sealing film 200 for a solar cell connects the substrate 210 and electrodes 312A and 312B of a solar cell 300, and the conducting wire structure 222 can cover the range of the electrodes 312A and 312B of the solar cell on the substrate 210. In other words, the layout of the conducting wire structure 222 on the substrate 210 can be less than (partial coverage) or equal to (full coverage) the range of the electrodes 312A and 312B. The present embodiment is exemplified by a full coverage configuration, but the disclosure is not limited thereto. The conducting wire structure only needs to be partially overlapped with the electrodes and electrically connect the electrodes of each of the solar cells.

As shown in FIG. 5A and FIG. 5B, the solar cell 300 includes a plurality of solar cell units 310, the conducting wire structure 222 includes a plurality of connecting conducting wires 222A, and each of the connecting conducting wires 222A connects the electrodes of adjacent solar cell units 310. More specifically, each of the solar cell units 310 includes a first solar cell unit 310A and a second solar cell unit 310B adjacent along the X direction, and each of the solar cell units 310 includes, for instance, a first electrode 312A and a second electrode 312B, wherein the first electrode 312A and the second electrode 312B are, for instance, respectively a positive electrode and a negative electrode. In each of the solar cell units 310 of the present embodiment, the first electrode 312A and the second electrode 312B are, for instance, strip electrodes parallelly disposed along the Y direction, wherein the first electrode 312A is located at one side of each of the solar cell units 310 along the X direction, and the second electrode 312B is located in the center of each of the solar cell units 310 along the X direction. As a result, as shown in FIG. 5A and FIG. 5B, each of the connecting conducting wires 222A covers and connects the first electrode 312A of the first solar cell unit 310A and the second electrode 312B of the second solar cell unit 310B, such that each of the connecting conducting wires 222A in the present embodiment forms a U pattern.

Moreover, in the present embodiment, the conducting wire structure 222 further includes a plurality of external conducting wires 222B located at an outermost side, and a portion of the substrate 210 corresponding to the external conducting wires 222B has at least one opening. For instance, in the present embodiment, the conducting wire structure 222 can include two external conducting wires 222B, and the portion of the substrate 210 corresponding to the two external conducting wires 222B can respectively have a first opening H1 and a second opening H2 via a lead wire hole punching method, and the solar cell module can be outputted and guided out via a subsequent lead wire soldering. Then, a suitable adhesive sealing material (such as a resin (epoxy) or a photocurable material) is soldered to the conducting wire such that the overall module can achieve a protective effect. Moreover, the number of hole punching at two ends of the lead wire is not limited, and the number can be increased to a plurality of holes at each end as needed.

It should be mentioned that, in comparison to the sealing structure for a known solar cell, the patterned adhesive layer 224 for sealing and adhering and the electrically connected conducting wire structure 222 in the sealing film 200 for a solar cell of the disclosure are disposed on the same layer, the conducting wire structure 222 is in direct contact with the substrate 210, and other film layers are not disposed between the conducting wire structure 222 and the substrate 210, and therefore when punching holes from the outside of the substrate 210 to form an opening for electrical output, only a portion of the material in the thickness of the substrate 210 needs to be removed to readily bond with the conducting wire structure 222 under the substrate 210. In contrast, in the sealing structure of prior art, at least a portion of material of each of the substrate 210 and the thickness of the adhesive layer 220 needs to be removed, and due to the adhesive properties of the adhesive layer 220 itself, hole punching is difficult and the adhesive layer 220 is readily adhered on the conducting wire structure 222 and readily remains on the conducting wire structure 222 as residue. As a result, issues such as poor electrical conduction and complex process readily occur. The electrical connection here is not limited to a serial connection, and can also be adjusted to 2 or more devices connected in parallel as needed, and the disclosure is not limited thereto.

Moreover, as shown in FIG. 5B, in the present embodiment, the sealing structure for a solar cell module can also further include a back film 400 disposed at a side opposite to the sealing film 200 for a solar cell, and the plurality of solar cell units 310 is between the sealing film 200 for a solar cell and the back film 400. In particular, the back film 400 is similar to the sealing film 200, and can be a back film containing an adhesive layer but without the conducting wire structure 222 or a back film without a general conducting wire structure for sealing the solar cell module and without an adhesive layer. In this case, an adhesive layer can be directly added when the back film is laminated to adhere the back film and the back side (not shown) of the solar cell to achieve the same effect.

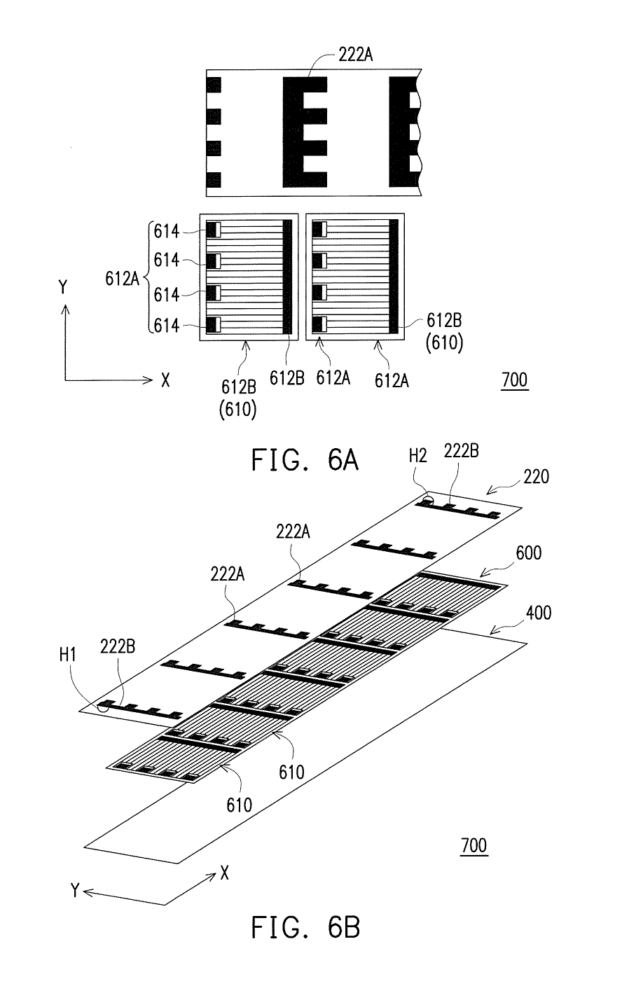

FIG. 6A and FIG. 6B show schematics of the second embodiment of the sealing structure for a solar cell module of the disclosure, wherein FIG. 6A shows a top view of the sealing film for a solar cell and the substrate in the sealing structure for a solar cell module of the second embodiment, and FIG. 6B shows a schematic of a laminated structure of the sealing structure for a solar cell module of the second embodiment. A sealing structure 700 for a solar cell module of the present embodiment is similar to the sealing structure 500 for a solar cell module of the first embodiment. However, the configuration of electrodes in each solar cell unit 610 in a solar cell 600 of the present embodiment is different from the configuration of electrodes in each of the solar cell units 310 in the solar cell 300 of the first embodiment.

Specifically, as shown in FIG. 6A and FIG. 6B, each of the solar cell units 610 includes a first electrode 612A disposed on the left side along the X direction and a second electrode 612B disposed on the right side along the X direction, wherein the first electrode 612A includes a plurality of first block-shaped electrodes 614 separated from one another parallelly and disposed along the Y direction, and the second electrode 612B is a strip electrode parallelly disposed along the Y direction. In the present embodiment, each of the connecting conducting wires 222A covers and connects the first electrode 612A of the first solar cell unit 610A and the second electrode 612B of the second solar cell unit 610B, such that each of the connecting conducting wires 222A forms a comb pattern in the present embodiment. Moreover, the other components of the sealing structure for a solar cell module of the present embodiment are the same as the other components of the sealing structure for a solar cell module of the first embodiment.

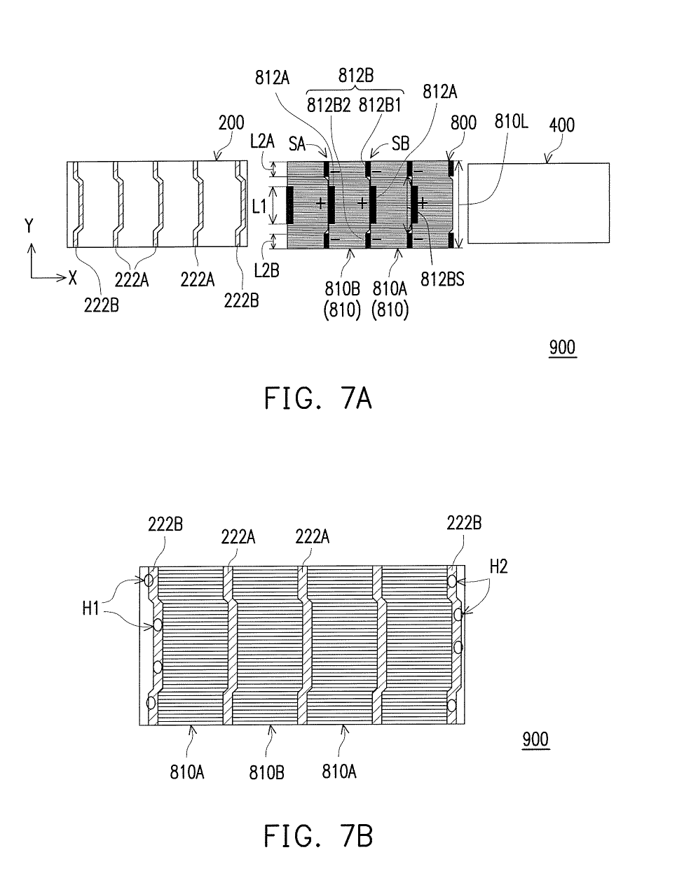

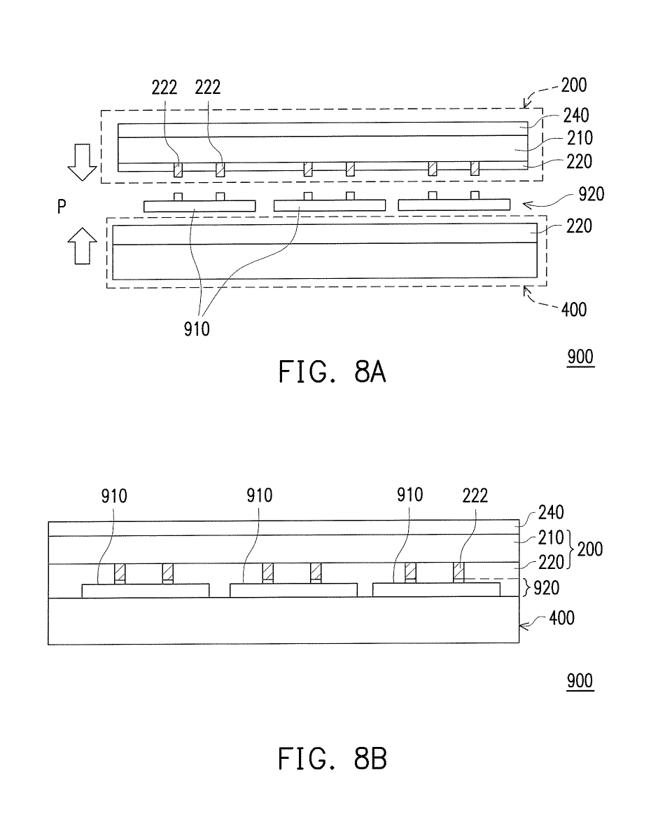

FIG. 7A and FIG. 7B show schematics of the third embodiment of the sealing structure for a solar cell module of the disclosure. A sealing structure 900 for a solar cell module of the present embodiment is similar to the sealing structures 500 and 700 for a solar cell module of the above embodiments. However, the configuration of electrodes in each solar cell unit 810 in a solar cell 800 of the present embodiment is different from the configuration of electrodes in each of the solar cell units 310 and 610 in the solar cells 300 and 600 of the above embodiments.

Specifically, as shown in FIG. 7A and FIG. 7B, in each of the solar cell units 810 of the present embodiment, a first electrode 812A is located at a first side SA (such as left side) of each of the solar cell units 810 along the X direction, and the first electrode 812A is a strip electrode parallelly disposed along the Y direction. The second electrode 812B is located at a second side SB (such as right side) of each of the solar cell units 810 along the X direction, the second electrode 812B includes two second block-shaped electrodes 812B1 and 812B2 parallelly disposed along the Y direction, the two second block-shaped electrodes 812B1 and 812B2 are separated from each other and respectively disposed at two ends of the second side SB of each of the solar cell units 810, and a separation space 812BS is between the two second block-shaped electrodes 812B1 and 812B2.

As shown in FIG. 7A and FIG. 7B, the projection of the first electrode 812A in the Y direction is located in the projection range of the separation space 812BS in the Y direction, and the sum of a length L1 of the first electrode 812A along the Y direction and the total of lengths L2A and L2B of the two second block-shaped electrodes 812B1 and 812B2 along the Y direction is less than or equal to a length 810L of each of the solar cell units 810 along the Y direction. In the present embodiment, each of the connecting conducting wires 222A alternately connects the second block-shaped electrode 812B1 of the first solar cell unit 810A, the first electrode 812A of the second solar cell unit 810B, and the second block-shaped electrode 812B2 of the first solar cell unit 810A in order in the Y direction to form a meandering pattern on the substrate 210. Moreover, the other components of the sealing structure 900 for a solar cell module of the present embodiment are the same as the other components of the sealing structures 500 and 700 for a solar cell module of the above embodiments.

In the present embodiment, the positive and negative electrodes of the solar cell unit 810 can be laid out in the form of line segments to reduce the usage amount of the conductive paste of the bus bar. The number of punched holes of the lead wire at two ends is not limited, and although four holes are shown at each of the two ends in FIG. 7B, a plurality (such as one each) holes can be provided at each of the two ends as needed.

Method of Manufacturing Sealing Structure for Solar Cell Module

FIG. 8A and FIG. 8B are flow charts of the method of manufacturing a sealing structure for a solar cell module of the disclosure. As shown in FIG. 8A, the method of manufacturing a sealing structure for a solar cell module includes the following steps. First, a sealing film 200 for a solar cell having the above structure is provided, and a solar cell 920 having a plurality of solar cell units 910 (can be the solar cell units 310, 610, and 810) is disposed on the adhesive layer 220 having the conducting wire structure 222 of the sealing film 200 for a solar cell. In the method of manufacturing a sealing structure for a solar cell module of the present embodiment, a back film 400 is further provided on the back side of the solar cell 920 such that the solar cell 920 is between the sealing film 200 for a solar cell and the back film 400. Then, a laminate step is performed on the sealing film 200 for a solar cell, the solar cell 920, and the back film 400, such that the conducting wire structure 222 of the sealing film 200 for a solar cell and the electrodes of the solar cell 920 are adhered after alignment. Accordingly, the sealing structure 900 for a solar cell module shown in FIG. 8B is obtained. It should be mentioned that, on the actual application layer, other film layers having other functions can be further formed on the substrate 210 as needed, such as a moisture barrier layer 240 shown in FIG. 8B, or a laminated layer such as a gas barrier, a UV absorption layer, a weather-ability layer, or an anti-scratch layer.

Referring to FIG. 8B, in short, the sealing structure for a solar cell module of the disclosure includes a sealing film 200 for a solar cell and a solar cell 920. The sealing film 200 for a solar cell includes a substrate 210 and an adhesive layer 220 having a conducting wire structure 222, wherein the adhesive layer 220 having the conducting wire structure 222 is disposed on the substrate 210, and the conducting wire structure 222 is in contact with the substrate 210. The solar cell 920 includes a plurality of solar cell units 910, the adhesive layer 220 is between the substrate 210 and the plurality of solar cell units 910, and the conducting wire structure 222 is in contact with the plurality of solar cell units 910 and the substrate 210.

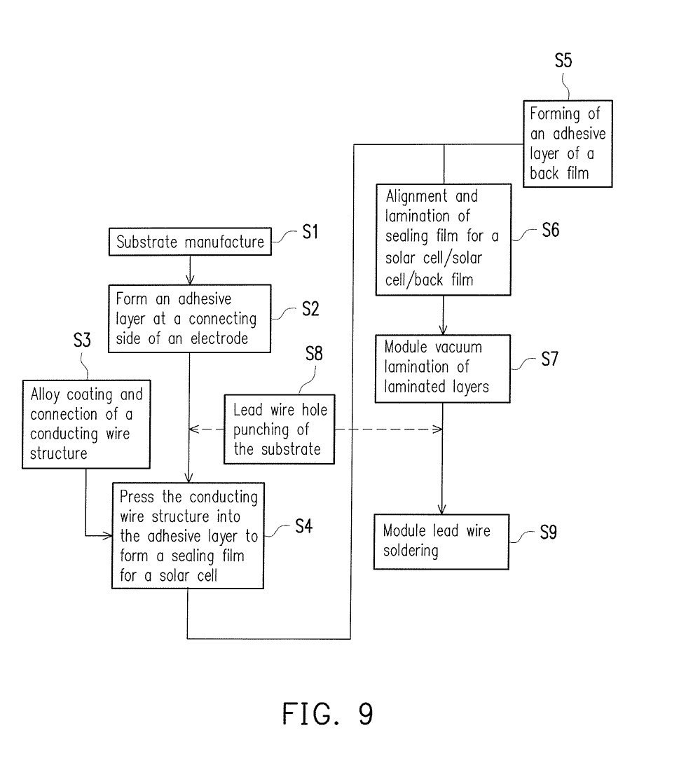

FIG. 9 is a flow chart of an embodiment of the method of manufacturing a sealing structure for a solar cell module of the third embodiment of the method of manufacturing a sealing film for a solar cell of the disclosure. As shown in FIG. 9, in step S1, the manufacture of a substrate is performed, wherein the substrate can be a single substrate or a laminated layer having other film layers having the functions of a gas barrier, a water barrier, or other functions on the outside as needed. Then, in step S2, an adhesive layer is formed at the connecting side of the electrode of the substrate, and the method of forming the adhesive layer in the present embodiment is exemplified in the form of FIGS. 4A-4D. Moreover, in step S3, the manufacture of a conducting wire structure is performed, such as providing a metal conducting wire and coating an alloy such as a low-temperature solder to be connected to the metal conducting wire. Then, in step S4, the conducting wire structure is pressed into the adhesive layer so as to form the sealing film for a solar cell. Then, in step S5, a back film can be provided as needed, and an adhesive layer can be formed on the back film. Next, in step S6, the sealing film for a solar cell and the solar cell obtained in step S4 and the back film of step S5 are aligned and laminated. Then, in step S7, thermal vacuum lamination is performed on the above laminated layer. Then, in step S8, a conducting wire hole punching process of the substrate can be performed, and the conducting wire hole punching method can adopt non-contact laser drilling or directly adopt mechanical hole punching. Of course, the step can also be performed earlier after step S2 in the substrate manufacturing process, and the disclosure is not limited thereto. Then, in step S9, a process of module lead wire soldering is performed.

Based on the above, the sealing film for a solar cell of the disclosure is in contact with the substrate via the conducting wire structure. Accordingly, via the contact force thereof, lateral displacement of the adhesive layer due to lamination in a subsequent process such as heating and melting does not occur between the conducting wire structure and the solar cell, and therefore the demand of maintaining accurate position of electrical connection is achieved. Moreover, in the method of manufacturing a sealing film for a solar cell of the disclosure, the electrically connected (not limited to serial connection or parallel connection) conducting wire structure, adhesive layer for sealing, and substrate material . . . etc. can be first integrated together, and sealing and electrical connection (such as serial connection or parallel connection) processes of the solar cell module can be completed via one heating and lamination process, and an additional adhesive layer is not needed. Moreover, due to the single-side electrical interconnection structure, the process is effectively simplified, and the overall solar cell module can be thinner, and influence to cell efficiency due to penetration by, for instance, water vapor, can be prevented.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A sealing film for a solar cell, comprising:
a substrate; and
an adhesive layer having a conducting wire structure disposed on the substrate, and the conducting wire structure is in contact with the substrate.

2. The sealing film for a solar cell of claim 1, wherein the conducting wire structure passes through a thickness direction of the adhesive layer.

3. The sealing film for a solar cell of claim 1, wherein the sealing film is electrically connected to the solar cell so as to form a sealing structure for a solar cell module with the solar cell.

4. The sealing film for a solar cell of claim 3, wherein the conducting wire structure connects the substrate and an electrode of the solar cell, and the conducting wire structure covers a range of the electrode of the solar cell on the substrate.

5. A sealing structure for a solar cell module, comprising:
a sealing film for a solar cell comprising a substrate and an adhesive layer having a conducting wire structure, wherein the adhesive layer having the conducting wire structure is disposed on the substrate, and the conducting wire structure is in contact with the substrate; and
a solar cell comprising a plurality of solar cell units, wherein the adhesive layer is between the substrate and the solar cell units, and the conducting wire structure is in contact with the solar cell units and the substrate.

6. The sealing structure for a solar cell module of claim 5, wherein the solar cell comprises a plurality of solar cell units, the conducting wire structure comprises a plurality of connecting conducting wires, and each of the connecting conducting wires connects electrodes of adjacent solar cell units.

7. The sealing structure for a solar cell module of claim 6, wherein each of the solar cell units comprises a first electrode and a second electrode, and each of the connecting conducting wires covers and connects a first electrode of one of the solar cell units and a second electrode of another one of the solar cell units adjacent to the solar cell unit.

8. The sealing structure for a solar cell module of claim 7, wherein in each of the solar cell units, the first electrode and the second electrode are strip electrodes parallelly disposed along a Y direction, wherein the first electrode is located at one side of each of the solar cell units along an X direction, and the second electrode is located in a center of each of the solar cell units along the X direction.

9. The sealing structure for a solar cell module of claim 7, wherein in each of the solar cell units, the first electrode comprises a plurality of first block-shaped electrodes parallelly disposed along the Y direction, the second electrode is a strip electrode parallelly disposed along the Y direction, and the first electrode and the second electrode are respectively disposed at two sides of each of the solar cell units.

10. The sealing structure for a solar cell module of claim 7, wherein in each of the solar cell units,
the first electrode is a strip electrode parallelly disposed along the Y direction and is disposed at a first side of each of the solar cell units along the X direction;
the second electrode comprises two second block-shaped electrodes parallelly disposed along the Y direction, the two second block-shaped electrodes are separated from each other and respectively disposed at two ends at a second side of each of the solar cell units, and a separation space is between the two second block-shaped electrodes;
a projection of the first electrode in the Y direction is located in a projection range of the separation space in the Y direction, and a sum of a length of the first electrode along the Y direction and a total length of the two second block-shaped electrodes along the Y direction is less than or equal to a length of each of the solar cell units along the Y direction.

11. The sealing structure for a solar cell module of claim 10, wherein each of the solar cell units comprises a first solar cell unit and a second solar cell unit adjacent along the X direction; and each of the connecting conducting wires alternately connects one of the two second block-shaped electrodes of the first solar cell unit, the first electrode of the second solar cell unit, and the other one of the two second block-shaped electrodes of the first solar cell unit in the Y direction to form a meandering pattern on the substrate.

12. The sealing structure for a solar cell module of claim 5, wherein the conducting wire structure further comprises a plurality of external conducting wires located at an outermost side, and a portion of the substrate corresponding to the external conducting wires has at least one opening.

13. The sealing structure for a solar cell module of claim 5, further comprising a back film disposed opposite to the sealing film for a solar cell, wherein the plurality of solar cell units is between the sealing film for a solar cell and the back film.

14. A method of manufacturing a sealing film for a solar cell, comprising:
providing a substrate; and
forming an adhesive layer having a conducting wire structure on the substrate, wherein the conducting wire structure is in contact with the substrate.

15. The method of claim 14, wherein the step of forming the adhesive layer having the conducting wire structure on the substrate comprises:
forming the conducting wire structure on the substrate; and
forming a patterned adhesive layer in a region outside the conductive wire structure on the substrate such that the patterned adhesive layer and the conductive wire structure form the adhesive layer.

16. The method of claim 14, wherein the step of forming the adhesive layer having the conducting wire structure on the substrate comprises:
forming a patterned adhesive layer on the substrate; and
forming the conducting wire structure in a region outside the patterned adhesive layer on the substrate, wherein the patterned adhesive layer and the conducting wire structure from the adhesive layer.

17. The method of claim 14, wherein the step of forming the adhesive layer having the conducting wire structure on the substrate comprises:
forming an adhesive material layer on the substrate; and
embedding the conducting wire structure in the adhesive material layer such that the conducting wire structure is in contact with the substrate.

18. The method of claim 17, wherein the step of embedding the conducting wire structure in the adhesive material layer comprises:
heating the adhesive material layer to soften the adhesive material layer, and then embedding the conducting wire structure in the softened adhesive material layer.

19. The method of claim 17, wherein the adhesive material layer comprises dissolving the adhesive material layer in an organic solvent, and performing heating on the adhesive material layer after the conducting wire structure is embedded in the adhesive material layer.

20. The method of claim 17, wherein the conducting wire structure comprises one or a plurality of protrusions in contact with the substrate, and each of the protrusions is an island-shaped pattern in contact with the substrate at a flat top surface thereof.

21. The method of claim 17, wherein the conducting wire structure comprises one or a plurality of protrusions in contact with the substrate, and each of the protrusions is an island-shaped pattern in contact with the substrate at a round top surface thereof.
